(19) United States
(12) Patent Application Publication
(10) Pub. No.: US 2009/0071704 A1
(43) Pub. Date: Mar. 19, 2009

(54) Circuit board and method for fabricating the same

(75) Inventor: Shih-Ping Hsu, Taiwan (CN)

Correspondence Address: EDWARDS ANGELL PALMER & DODGE LLP, P.O. BOX 55874, BOSTON, MA, 02205, US

(73) Assignee: Phoenix Precision Technology Corporation, Hsin-Chu (TW)

(21) Appl. No.: 12/284,324

(22) Filed: Sep. 19, 2008

(30) Foreign Application Priority Data
Sep. 19, 2007 (TW) 096134795

(51) Int. Cl. H05K 1/11; H05K 3/10

(52) U.S. Cl. 174/261; 29/846

(57) ABSTRACT

A circuit board and a method for fabricating the same are disclosed. The circuit board includes: a carrier board having a circuit layer formed on at least one surface thereof; a first dielectric layer formed on the carrier board and having first openings for exposing a part of the circuit layer; conductive vias formed in the first openings; a second dielectric layer formed on the first dielectric layer and having second and third openings formed therein, wherein the second openings correspond to the first openings for exposing the conductive vias; and a multi-layered metal electroless plating circuit layer formed in the second and third openings for electrically connecting the circuit layer of the carrier board via the conductive vias, thereby allowing the multi-layered metal electroless plating circuit layer to be embedded into the first and second dielectric layers to enhance the bonding strength therebetween and increase the reliability of the circuit board and facilitate formation of fine circuits.

### BACKGROUND OF THE INVENTION

1. Field of the Invention

The present invention relates generally to circuit boards and methods for fabricating the same, and more particularly to a circuit board with circuit and conductive vias formed by means of chemical deposition and a method for fabricating the same.

2. Description of Related Art

Along with the rapid development of electronic industries, R&D efforts are being focused on multi-functional and high-performance electronic products. Meanwhile, package substrates for receiving semiconductor chips are developed from two-layer boards to multi-layer boards so as to increase the available circuit layout area by using interlayer connection technique and accommodate more circuits and elements in a unit area, thereby meeting packaging requirement of high integration and miniaturization.

In order to meet operation requirements of microprocessors, chipsets and graphic chips, circuit boards for receiving semiconductor chips also need to improve functions including chip signal transmission, bandwidth improvement and resist control so as to achieve the development of semiconductor packages with high I/O connections. In order to meet requirements such as miniaturization, multi-function, high speed and multiplexing for semiconductor packages, circuit boards are gradually developed with fine circuits and small conductive vias. The circuit size such as a line width and a circuit space in the current circuit board fabricating method has reduced from traditional 100 μm to less than 30 μm. Also, finer circuits are likely to be developed in the near future.

In order to enhance the circuit layout density and precision, a circuit build-up technique is proposed, through which a plurality of dielectric layers and circuit layers are alternately stacked on a core board and conductive vias are formed in the dielectric layers for electrically connecting upper and lower circuits. The circuit build-up technique is a key element in determining circuit density of circuit boards and such a technique is widely applied in the current industry to fabricate multi-layer circuit boards.

FIGS. 1A to 1E show a semi-additive process (SAP) of performing the build-up process. As shown in FIG. 1A, a carrier board 10 having a first circuit layer 101 formed on a surface thereof is provided. As shown in FIG. 1B, a dielectric layer 11 is formed on the carrier board 10 and a plurality of openings 110 is formed in the dielectric layer 11 by laser drilling so as to expose the first circuit layer 101 of the carrier board 10. Then, as shown in FIG. 1C, a conductive layer 12 is formed on the dielectric layer 11 by means of electroless copper plating and a resist layer 13 is formed on the conductive layer 12, wherein the resist layer 13 has a plurality of openings 130 for exposing a part of the surface of the conductive layer 12. Thereafter, as shown in FIG. 1D, a second circuit layer 14 is formed in the openings 130 of the resist layer 13 by electroplating and conductive vias 141 are formed in the openings 110 of the dielectric layer 11 for electrically connecting the first circuit layer 101 of the carrier board 10. Subsequently, the resist layer 13 and the conductive layer 12 covered by the resist layer 12 are removed, as shown in FIG. 1E. By repeating the above-described processes to form dielectric layers and circuit layers, a circuit board with multi-layer circuits is obtained.

However, when circuit becomes finer and spacing between circuits becomes smaller, the spacing may not be wholly filled with a dielectric layer in a circuit build-up process such that air bubbles remain in the structure, thus adversely affecting the reliability of the circuit board. In addition, since there is a much smaller contact area between the bottom of the fine circuit and the dielectric layer, the bonding strength therebetween is quite poor.

Further, variation of the current density across the conductive layer functioning as a current conductive path during electroplating leads to an uneven thickness of the circuit layer formed on the conductive layer, thereby adversely affecting the uniformity of the circuit layer and the electrical performance.

Therefore, how to provide a circuit board and a method for fabricating the same so as to overcome the above-described drawbacks has become urgent.

### SUMMARY OF THE INVENTION

According to the above drawbacks of the prior art, an object of the present invention is to provide a circuit board and a method for fabricating the same so as to enhance the bonding strength between the circuit layer and the dielectric layer of the circuit board.

Another object of the present invention is to provide a circuit board and a method for fabricating the same so as to form fine circuit structure.

A further object of the present invention is to provide a circuit board and a method for fabricating the same so as to improve uniformity in thickness of the circuit of the circuit board.

In order to attain the above and other objects, the present invention provides a circuit board, which comprises: a carrier board having a circuit layer formed on at least one surface thereof; a first dielectric layer formed on the carrier board and having first openings for exposing a part of the circuit layer; conductive vias formed in the first openings for electrically connecting the circuit layer; a second dielectric layer formed on the first dielectric layer and having second and third openings formed therein, wherein the second openings correspond in position to the first openings to expose the conductive vias; and a multi-layered metal electroless plating circuit layer formed in the second and third openings for electrically connecting the circuit layer of the carrier board via the conductive vias in the first openings.

According to another embodiment, the circuit board comprises: a carrier board having a circuit layer formed on at least one surface thereof; a first dielectric layer formed on the carrier board and having first openings for exposing a part of the circuit layer; a second dielectric layer formed on the first dielectric layer and having second and third openings formed therein, wherein the second openings correspond in position to the first openings to expose the part of the circuit layer exposed from the first openings; and a multi-layered metal electroless plating circuit layer formed in the second and third openings, wherein conductive vias are formed in the first openings to electrically connect the circuit layer of the carrier board.

The present invention further provides a method for fabricating a circuit board, which comprises: providing a carrier board having a circuit layer formed on at least one surface thereof; forming a first dielectric layer on the carrier board, with first openings formed in the first dielectric layer to expose a part of the circuit layer; forming conductive vias in the first openings by chemical deposition; forming a second dielectric layer on the first dielectric layer and the conductive vias, with second openings and third openings formed in the second dielectric layer, wherein the second openings correspond in position to the first openings to expose the conductive vias and a part of the first dielectric layer; and forming a multi-layered metal electroless plating circuit layer in the second and third openings, wherein the multi-layered metal electroless plating circuit layer electrically connecting the circuit layer of the carrier board via the conductive vias.

According to another embodiment, the method for fabricating a circuit board comprises: providing a carrier board having a circuit layer formed on at least one surface thereof; forming a first dielectric layer on the carrier board for covering the circuit layer and forming first openings in the first dielectric layer for exposing a part of the circuit layer; forming a second dielectric layer on the first dielectric layer and the part of the circuit layer exposed from the first openings, with second openings and third openings formed in the second dielectric layer, wherein the second openings correspond in position to the first openings to expose the part of the circuit layer exposed from the first openings; and forming a multi-layered metal electroless plating circuit layer in the first, second and third openings, wherein conductive vias are formed in the first openings to electrically connect the circuit layer of the carrier board.

According to another embodiment, the method for fabricating a circuit board comprises: providing a carrier board having a circuit layer formed on at least one surface thereof; forming a first dielectric layer and a second dielectric layer in sequence on the carrier board; forming second openings and third openings in the second dielectric layer to expose a part of the first dielectric layer; forming first openings in the part of the first dielectric layer exposed from the second openings to expose a part of the circuit layer; and forming a multi-layered metal electroless plating circuit layer in the first, second and third openings, wherein conductive vias are formed in the first openings to electrically connect the circuit layer of the carrier board.

In the above-described circuit boards and methods for fabricating the same, the carrier board is one of an insulation board and a circuit board with multi-layer circuits, the conductive vias are made of one of a three-layer material of Cu/Ni/Cu, a four-layer material of Cu/Ni/Au/Cu, and a five-layer material of Cu/Ni/Pd/Au/Cu, and the multi-layered metal electroless plating circuit layer is made of one of a three-layer material of Cu/Ni/Cu, a four-layer material of Cu/Ni/Au/Cu, and a five-layer material of Cu/Ni/Pd/Au/Cu.

The present invention forms a multi-layered metal electroless plating circuit layer by means of chemical deposition that is so called electroless plating, in a first dielectric layer and a second dielectric layer so as to increase the contact area between the multi-layered metal electroless plating circuit layer and the first and second dielectric layers, thereby enhancing the bonding strength therebetween and also preventing air bubbles from being remained in the circuit board as in the prior art because spacing between circuits is not wholly filled by the dielectric layer. Further, the chemical deposition process improves uniformity in thickness of the circuit structure and facilitates formation of fine circuits, thereby overcoming the conventional drawbacks of uneven thickness of circuit caused by variation of current density across the conductive layer and difficulty in formation of fine circuits.

### BRIEF DESCRIPTION OF DRAWINGS

FIGS. 1A to 1E are sectional views showing a conventional semi-additive method for fabricating a circuit board;

FIGS. 2A to 2E are sectional views showing a method for fabricating a circuit board according to a first embodiment of the present invention, wherein FIG. 2A′ is a sectional view showing another embodiment of FIG. 2A;

FIGS. 3A to 3D are sectional views showing a method for fabricating a circuit board according to a second embodiment of the present invention; and

FIGS. 4A to 4D are sectional views showing a method for fabricating a circuit board according to a third embodiment of the present invention.

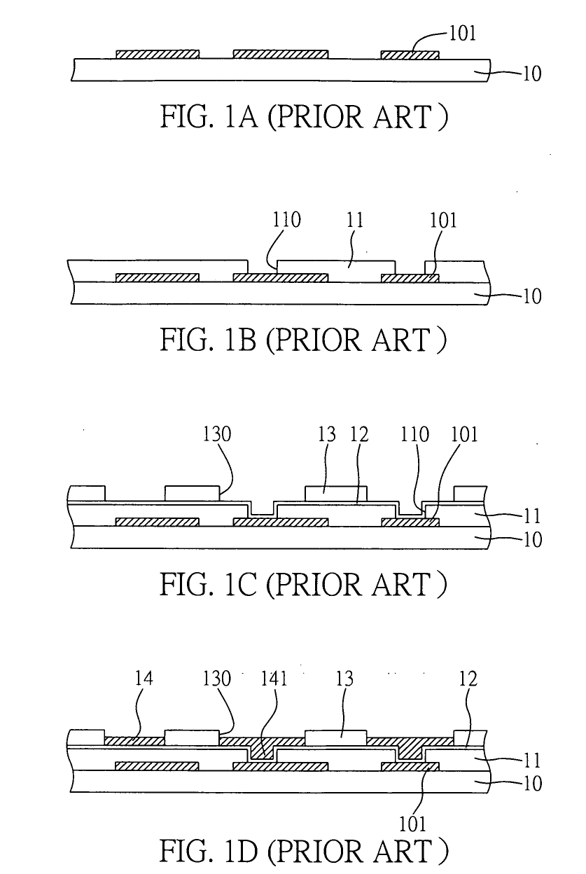

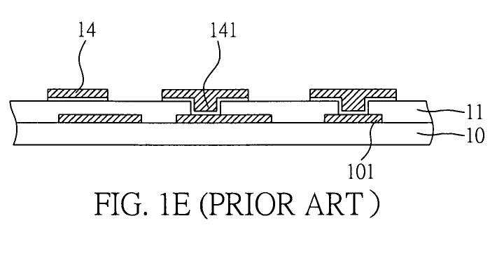

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification.

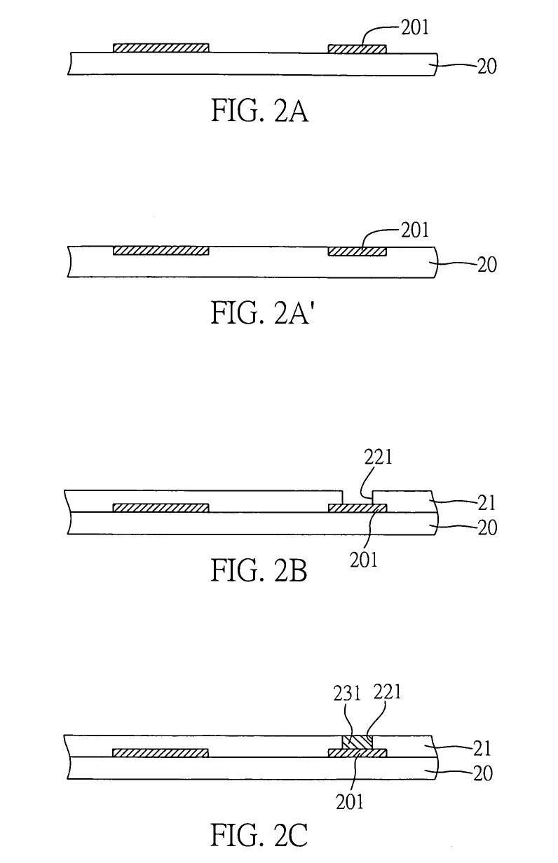

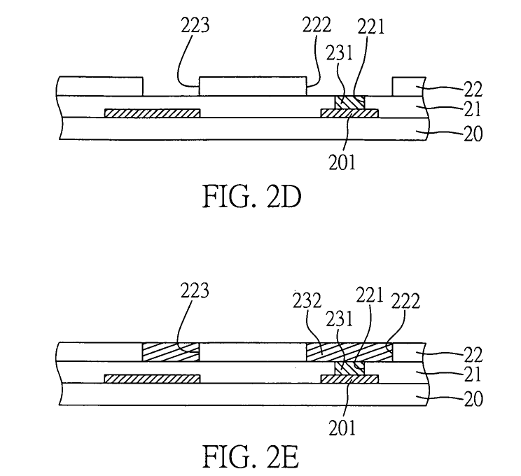

FIGS. 2A to 2E are sectional views showing a method for fabricating a circuit board according to a first embodiment of the present invention.

As shown in FIG. 2A, a carrier board 20 having a circuit layer 201 formed on a surface thereof is provided. The carrier board 20 may be an insulation board or a circuit board with multi-layer circuits. Alternatively, as shown in FIG. 2A′, the circuit layer 201 can be embedded in the dielectric layer of the carrier board. Hereinafter, the structure as shown in FIG. 2A is exemplified for description.

As shown in FIG. 2B, a first dielectric layer 21 is formed on the carrier board 20, and a plurality of first openings 221 is formed by means of laser drilling or exposure and development in the first dielectric layer 21 to expose a part of the circuit layer 201. Therein, the first dielectric layer 21 may be made of a photosensitive material or a non-photosensitive material, which may be made of ABF, epoxy resin, polyimide, cyanate ester, glass fiber, BT or FR5 (a mixture of epoxy resin and glass fiber).

As shown in FIG. 2C, conductive vias 231 are formed in the first openings 221 of the first dielectric layer 21 by means of chemical deposition that is so called electroless plating. The conductive vias 231 may be made of one of a three-layer material of Cu/Ni/Cu, a four-layer material of Cu/Ni/Au/Cu, and a five-layer material of Cu/Ni/Pd/Au/Cu.

As shown in FIG. 2D, a second dielectric layer 22 is formed on the first dielectric layer 21, and second openings 222 and third openings 223 are formed by means of laser drilling or exposure and development in the second dielectric layer 22. Therein, the second openings 222 correspond in position to the first openings 221 for exposing the conductive vias 231. The second dielectric layer 22 may be made of a photosensitive material or a non-photosensitive material, which may be made of ABF, epoxy resin, polyimide, cyanate ester, glass fiber, BT or FR5 (a mixture of epoxy resin and glass fiber).

Finally, as shown in FIG. 2E, a multi-layered metal electroless plating circuit layer 232 is formed by means of chemical deposition in the second openings 222 and the third openings 223, and the multi-layered metal electroless plating circuit layer 232 electrically connecting the circuit layer 201 of the carrier board 20 via the conductive vias 231. The multi-layered metal electroless plating circuit layer 232 may be made of one of a three-layer material of Cu/Ni/Cu, a four-layer material of Cu/Ni/Au/Cu, and a five-layer material of Cu/Ni/Pd/Au/Cu.

The present invention provides a circuit board, which comprises: a carrier board 20 having a circuit layer 201 formed on at least one surface thereof; a first dielectric layer 21 formed on the carrier board 20 and having a plurality of first openings 221 for exposing a part of the circuit layer 201 of the carrier board 20; conductive vias 231 formed in the first openings 221 for electrically connecting the circuit layer 201; a second dielectric layer 22 formed on the first dielectric layer 21 and having second openings 222 and third openings 223, wherein the second openings 222 correspond in position to the first openings 221 to expose the conductive vias 231; and a multi-layered metal electroless plating circuit layer 232 formed in the second openings 222 and the third openings 223 for electrically connecting the circuit layer 201 of the carrier board 20 via the conductive vias 231 in the first openings 221.

In the above-described structure, the carrier board is one of an insulation board and a circuit board with multi-layer circuits. The multi-layered metal electroless plating circuit layer and conductive vias are made of one of a three-layer material of Cu/Ni/Cu, a four-layer material of Cu/Ni/Au/Cu, and a five-layer material of Cu/Ni/Pd/Au/Cu. The above-described steps can be repeated according to practical electrical design so as to obtain a circuit board with multi-layer circuits.

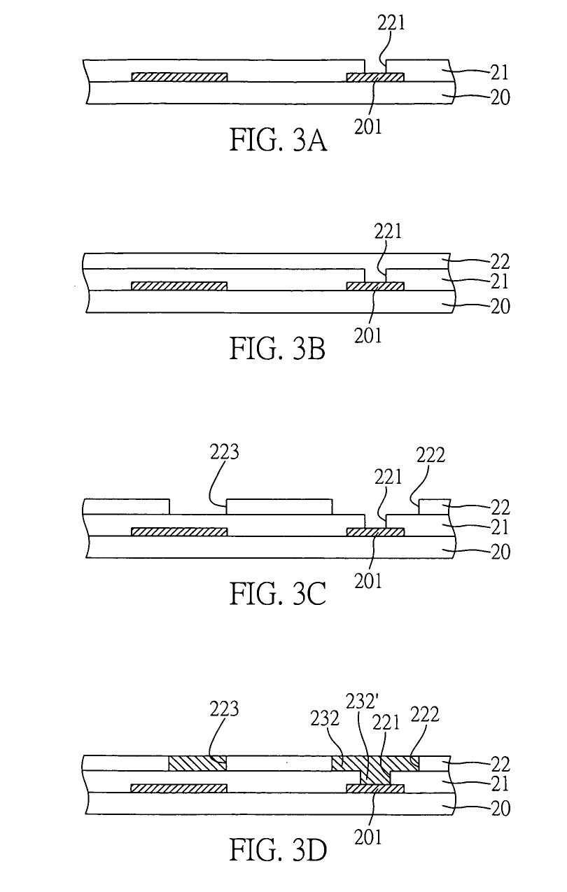

As shown in FIGS. 3A to 3D, a method for fabricating a circuit board according to a second embodiment of the present invention is shown. A difference of the present embodiment from the first embodiment is the second dielectric layer is formed on the first dielectric layer with the first openings before the conductive vias are formed in the first openings of the first dielectric layer.

As shown in FIG. 3A, a carrier board 20 having a circuit layer 201 formed on the upper surface thereof as shown in FIG. 2A is provided. A first dielectric layer 21 is formed on the carrier board 20 and first openings 221 is formed in the first dielectric layer 21 for exposing a part of the circuit layer 201.

As shown in FIG. 3B, a second dielectric layer 22 is formed on the first dielectric layer 21 and the part of the circuit layer 201 exposed from the first openings 221.

As shown in FIG. 3C, second openings 222 and third openings 223 are formed in the second dielectric layer 22, wherein the second openings 222 are located on the first openings 221 for exposing a part of the circuit layer 201.

Finally, as shown in FIG. 3D, by means of chemical deposition, a multi-layered metal electroless plating circuit layer 232 is formed in the first, second and third openings 221, 222, 223, and conductive vias 232′ are formed in the first openings 221 to electrically connect the circuit layer 201 such that the multi-layered metal electroless plating circuit layer 232 can be electrically connected to the circuit layer 201 through the conductive vias 232′. Therein, the multi-layered metal electroless plating circuit layer 232 is made of one of a three-layer material of Cu/Ni/Cu, a four-layer material of Cu/Ni/Au/Cu, and a five-layer material of Cu/Ni/Pd/Au/Cu. The above-described steps can be repeated according to practical electrical design so as to obtain a circuit board with multi-layer circuits.

The present invention further provides a circuit board, which comprises: a carrier board 20 having a circuit layer 201 formed on at least one surface thereof; a first dielectric layer 21 formed on the carrier board 20 and having first openings 221 for exposing a part of the circuit layer 201 of the carrier board 20; a second dielectric layer 22 formed on the first dielectric layer 21 and having second openings 222 and third openings 223, wherein the second openings 222 correspond in position to the first openings 221 for exposing a part of the surfaces of the circuit layer 201; and a multi-layered metal electroless plating circuit layer 232 formed in the first openings 221, the second openings 222 and the third openings 223, wherein conductive vias 232′ are formed in the first openings 221 to electrically connect the circuit layer 201 of the carrier board 20.

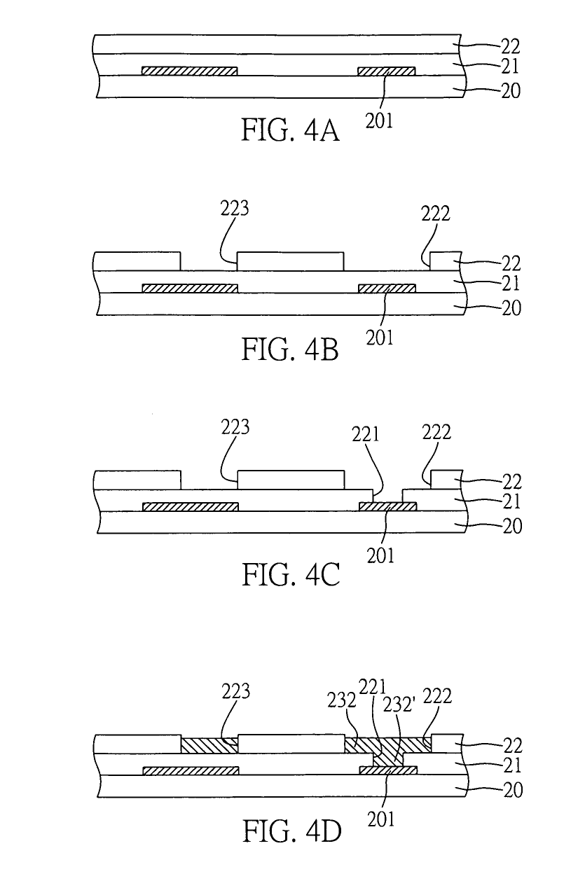

FIGS. 4A to 4D show a method for fabricating a circuit board according to a third embodiment of the present invention. A difference of the present embodiment from the second embodiment is the first dielectric layer and the second dielectric layer are formed in sequence on the carrier board before the first to third openings are respectively formed therein.

As shown in FIG. 4A, a carrier board 20 having a circuit layer 201 formed on a surface thereof as shown in FIG. 2A is provided, and a first dielectric layer 21 and a second dielectric layer 22 are formed in sequence on the carrier board 20.

As shown in FIG. 4B, second openings 222 and third openings 223 are formed in the second dielectric layer 22 to expose a part of the first dielectric layer 21.

As shown in FIG. 4C, first openings 221 are formed in the part of the first dielectric layer 21 exposed from the second openings 222 so as to expose the circuit layer 201.

As shown in FIG. 4D, conductive vias 232′ are formed by means of chemical deposition in the first openings 221 to electrically connect the circuit layer 201, and a multi-layered metal electroless plating circuit layer 232 is formed in the second and third openings 222, 223.

The present invention mainly involves forming a multi-layered metal electroless plating circuit layer by means of chemical deposition in a first dielectric layer and a second dielectric layer so as to increase the contact area between the multi-layered metal electroless plating circuit layer and the first and second dielectric layers, thereby enhancing the bonding strength therebetween and also preventing air bubbles from being remained in the circuit board as in the prior art because spacing between circuits is not wholly filled by the dielectric layer. Further, the chemical deposition process improves uniformity in thickness of the circuit structure and facilitates formation of fine circuits, thereby overcoming the conventional drawbacks of uneven thickness of circuit caused by variation of current density across the conductive layer and difficulty in formation of fine circuits.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A circuit board, comprising:
a carrier board having a circuit layer formed on at least one surface thereof;
a first dielectric layer formed on the carrier board and having first openings for exposing a part of the circuit layer;
conductive vias formed in the first openings for electrically connecting the circuit layer;
a second dielectric layer formed on the first dielectric layer and having second openings and third openings formed therein, wherein the second openings correspond in position to the first openings to expose the conductive vias; and
a multi-layered metal electroless plating circuit layer formed in the second openings and the third openings for electrically connecting the circuit layer of the carrier board via the conductive vias in the first openings.

2. The circuit board of claim 1, wherein the carrier board is one of an insulation board and a circuit board with multi-layer circuits.

3. The circuit board of claim 1, wherein the conductive vias are made of one of a three-layer material of Cu/Ni/Cu, a four-layer material of Cu/Ni/Au/Cu, and a five-layer material of Cu/Ni/Pd/Au/Cu.

4. The circuit board of claim 1, wherein the multi-layered metal electroless plating circuit layer is made of one of a three-layer material of Cu/Ni/Cu, a four-layer material of Cu/Ni/Au/Cu, and a five-layer material of Cu/Ni/Pd/Au/Cu.

5. A circuit board, comprising:
a carrier board having a circuit layer formed on at least one surface thereof;
a first dielectric layer formed on the carrier board and having first openings for exposing a part of the circuit layer;
a second dielectric layer formed on the first dielectric layer and having second openings and third openings formed therein, wherein the second openings correspond in position to the first openings to expose the part of the circuit layer exposed from the first openings; and
a multi-layered metal electroless plating circuit layer formed in the second openings and the third openings, wherein conductive vias are formed in the first openings to electrically connect the circuit layer of the carrier board.

6. The circuit board of claim 5, wherein the carrier board is one of an insulation board and a circuit board with multi-layer circuits.

7. The circuit board of claim 5, wherein the multi-layered metal electroless plating circuit layer is made of one of a three-layer material of Cu/Ni/Cu, a four-layer material of Cu/Ni/Au/Cu, and a five-layer material of Cu/Ni/Pd/Au/Cu.

8. A method for fabricating a circuit board, comprising:
providing a carrier board having a circuit layer formed on at least one surface thereof;
forming a first dielectric layer on the carrier board, with first openings formed in the first dielectric layer to expose a part of the circuit layer;
forming conductive vias in the first openings by chemical deposition;
forming a second dielectric layer on the first dielectric layer and the conductive vias, with second openings and third openings formed in the second dielectric layer, wherein the second openings correspond in position to the first openings to expose the conductive vias and a part of the first dielectric layer; and
forming a multi-layered metal electroless plating circuit layer in the second openings and the third openings, wherein the multi-layered metal electroless plating circuit layer electrically connects the circuit layer of the carrier board via the conductive vias.

9. The method of claim 8, wherein the carrier board is one of an insulation board and a circuit board with multi-layer circuits.

10. The method of claim 8, wherein the conductive vias are made of one of a three-layer material of Cu/Ni/Cu, a four-layer material of Cu/Ni/Au/Cu, and a five-layer material of Cu/Ni/Pd/Au/Cu.

11. The method of claim 8, wherein the multi-layered metal electroless plating circuit layer is made of one of a three-layer material of Cu/Ni/Cu, a four-layer material of Cu/Ni/Au/Cu, and a five-layer material of Cu/Ni/Pd/Au/Cu.

12. A method for fabricating a circuit board, comprising:
providing a carrier board having a circuit layer formed on at least one surface thereof;
forming a first dielectric layer on the carrier board for covering the circuit layer and forming first openings in the first dielectric layer for exposing a part of the circuit layer;
forming a second dielectric layer on the first dielectric layer and the part of the circuit layer exposed from the first openings, with second openings and third openings formed in the second dielectric layer, wherein the second openings correspond in position to the first openings to expose the part of the circuit layer exposed from the first openings; and
forming a multi-layered metal electroless plating circuit layer in the first openings, the second openings and the third openings, wherein conductive vias are formed in the first openings to electrically connect the circuit layer of the carrier board.

13. The method of claim 12, wherein the carrier board is one of an insulation board and a circuit board with multi-layer circuits.

14. The method of claim 12, wherein the multi-layered metal electroless plating circuit layer is made of one of a three-layer material of Cu/Ni/Cu, a four-layer material of Cu/Ni/Au/Cu, and a five-layer material of Cu/Ni/Pd/Au/Cu.

15. A method for fabricating a circuit board, comprising:
providing a carrier board having a circuit layer formed on at least one surface thereof;
forming a first dielectric layer and a second dielectric layer in sequence on the carrier board;
forming second openings and third openings in the second dielectric layer to expose a part of the first dielectric layer;
forming first openings in the part of the first dielectric layer exposed from the second openings to expose a part of the circuit layer; and
forming a multi-layered metal electroless plating circuit layer in the first openings, the second openings and the third openings, wherein conductive vias are formed in the first openings to electrically connect the circuit layer of the carrier board.

16. The method of claim 15, wherein the carrier board is one of an insulation board and a circuit board with multi-layer circuits.

17. The method of claim 15, wherein the conductive vias are made of one of a three-layer material of Cu/Ni/Cu, a four-layer material of Cu/Ni/Au/Cu, and a five-layer material of Cu/Ni/Pd/Au/Cu.

18. The method of claim 15, wherein the multi-layered metal electroless plating circuit layer is made of one of a three-layer material of Cu/Ni/Cu, a four-layer material of Cu/Ni/Au/Cu, and a five-layer material of Cu/Ni/Pd/Au/Cu.
